(19) United States
(12) Patent Application Publication
(10) Pub. No.: US 2026/0153542 A1
(43) Pub. Date: Jun. 4, 2026

(54) POWER CONSUMPTION LEVEL MEASUREMENT DEVICE AND POWER CONSUMPTION LEVEL MEASUREMENT METHOD

(71) Applicant: REALTEK SEMICONDUCTOR CORPORATION, HSINCHU (TW)

(72) Inventors: SHIH-AN YANG, Hsinchu (TW); CHAO-MIN LAI, Hsinchu (TW); GUO-YUAN LUO, Hsinchu (TW)

(21) Appl. No.: 18/964,738

(22) Filed: Dec. 2, 2024

(30) Foreign Application Priority Data
Feb. 19, 2024 (TW) 113105862

(51) Int. Cl. G01R 21/133

(52) U.S. Cl. CPC G01R 21/133

(57) ABSTRACT

A power consumption level measurement device includes a time-division multiplexing meter and a time-division multiplexing calculator. The time-division multiplexing meter includes a plurality of measurement terminals. The plurality of measurement terminals are configured to measure a plurality of power consumption levels of a plurality of devices under test. The time-division multiplexing calculator is configured to set the plurality of power consumption levels to a common time reference, and calculate a plurality of measurement values of the plurality of power consumption levels.

### BACKGROUND OF THE INVENTION

### 1. Field of the Invention

The present disclosure relates to a power consumption level measurement device and a power consumption level measurement method, especially to a power consumption level measurement device and a power consumption level measurement method that synchronously measure a plurality of power consumption levels.

### 2. Description of Related Art

In order to implement multichannel analog-to-digital conversion (ADC) functionality, when measuring power consumption levels of multiple power rails of a measurement system, it is necessary to use a power analyzer. However, the number of measurement channels supported by the power analyzer is limited. Generally, multiple power analyzers are needed to simultaneously measure the power consumption levels of multiple power rails. In view of the above, the cost and complexity of the measurement process increases, and it is extremely difficult to maintain synchronization between multiple power analyzers.

### SUMMARY OF THE INVENTION

In some aspects, an object of the present disclosure is to, but not limited to, provides a power consumption level measurement device and a power consumption level measurement method that makes an improvement to the prior art.

An embodiment of the power consumption level measurement device of the present disclosure includes a time-division multiplexing meter and a time-division multiplexing calculator. The time-division multiplexing meter includes a plurality of measurement terminals. The plurality of measurement terminals are configured to measure a plurality of power consumption levels of a plurality of devices under test. The time-division multiplexing calculator is configured to set the plurality of power consumption levels to a common time reference, and calculate a plurality of measurement values of the plurality of power consumption levels.

An embodiment of the power consumption level measurement method of the present disclosure includes: respectively measuring a plurality of power consumption levels of a plurality of devices under test by a plurality of measurement terminals of a time-division multiplexing meter; and setting the plurality of power consumption levels to a common time reference and calculating a plurality of measurement values of the plurality of power consumption levels by a time-division multiplexing calculator.

Technical features of some embodiments of the present disclosure make an improvement to the prior art. The power consumption level measurement device and the power consumption level measurement method of the present disclosure can synchronously measure the power consumption levels of the plurality of devices under test to address the problem of asynchrony between the power consumption level measurement devices. Besides, the present disclosure only needs to use a single power consumption level measurement device for executing the power consumption level measurement, thereby saving costs, and reducing measurement complexity.

These and other objectives of the present invention will no doubt become obvious to those of ordinary skill in the art after reading the following detailed description of the preferred embodiments that are illustrated in the various figures and drawings.

### BRIEF DESCRIPTION OF THE DRAWINGS

FIG. 1 shows an embodiment of a power consumption level measurement device and a device under test of the present disclosure.

FIG. 2 shows an embodiment of a flow diagram of a power consumption level measurement method of the present disclosure.

FIG. 3 shows an embodiment of power consumption level and time frames of the present disclosure.

### DETAILED DESCRIPTION OF THE PREFERRED EMBODIMENTS

To address the problem of asynchrony between multiple power consumption level measurement devices in the prior art, the present disclosure provides a power consumption level measurement device and a power consumption level measure method, which will be explained in detail as shown below.

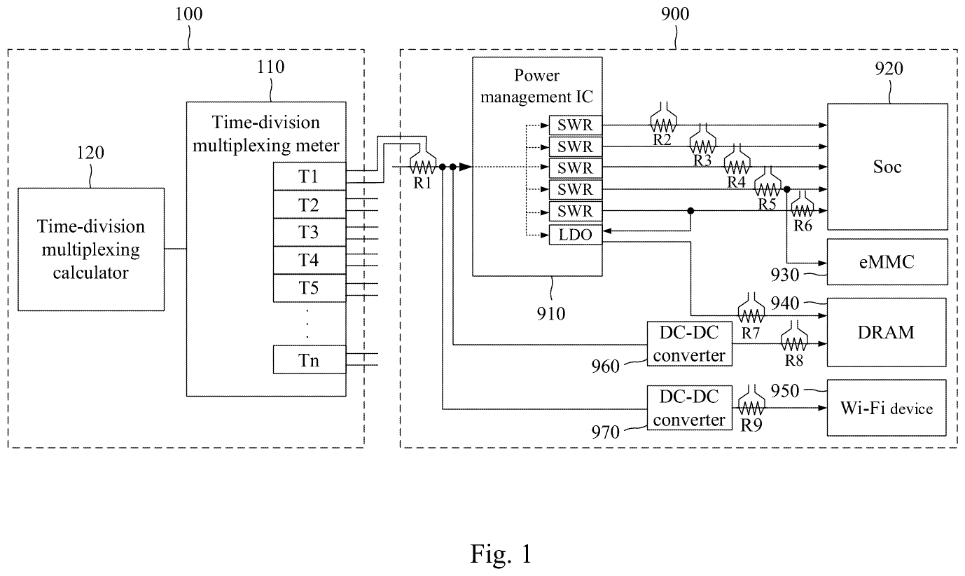

FIG. 1 shows an embodiment of a power consumption level measurement device 100 and a device under test 900 of the present disclosure. As shown in the figure, the power consumption level measurement device 100 includes a time-division multiplexing meter 110 and a time-division multiplexing calculator 120. The time-division multiplexing meter 110 includes a plurality of measurement terminals T1˜Tn.

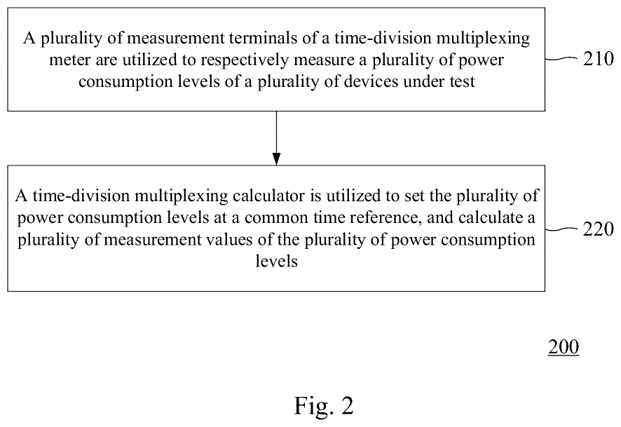

For facilitating the understanding of the operations of the power consumption level measurement device 100, reference is now made to FIG. 2. FIG. 2 shows an embodiment of a flow diagram of a power consumption level measurement method 200 of the present disclosure.

In step 210, the plurality of measurement terminals T1˜Tn of the time-division multiplexing meter 110 are utilized to respectively measure a plurality of power consumption levels of a plurality of devices under test. For example, the device under test 900 includes multiple devices requiring power consumption level measurement. The multiple devices can be, for example, a power management IC 910, a SoC(single-chip system) 920, an eMMC(embedded multimedia card) 930, a DRAM (dynamic random access memory) 940, and a Wi-Fi device 950, all of which need power consumption level measurement. The plurality of measurement terminals T1˜Tn of the time-division multiplexing meter 110 of the present disclosure are utilized to respectively measure the plurality of power consumption levels of the above-mentioned multiple devices. Specifically, the plurality of measurement terminals T1˜Tn of the time-division multiplexing meter 110 of the present disclosure can measure the power consumption level of the power management IC 910 through a resistor R1, respectively measure multiple power consumption levels (e.g., power consumption level of CPU, power consumption level of Core) of the SoC 920 through resistors R2˜R6, measure the power consumption level of the DRAM 940 through resistors R7, R8, and measure the power consumption level of the Wi-Fi device 950 through a resistor R9.

In some embodiments, the time-division multiplexing meter 110 can be a TDM (Time-Division Multiplexing) analog-to-digital converter. In some embodiments, the number of the plurality of measurement terminals T1˜Tn of the time-division multiplexing meter 110 can be at least five. In some embodiments, the plurality of measurement terminals T1˜Tn of the time-division multiplexing meter 110 can be a plurality of channels. However, the above-mentioned embodiment is merely utilized to describe one of the implementations, and the present disclosure is not limited thereto. In another embodiment, the time-division multiplexing meter 110 and the measurement terminals T1˜Tn can be implemented by other electronic device/element based on actual requirements.

In step 220, the time-division multiplexing calculator 120 is utilized to set the plurality of power consumption levels at a common time reference, and calculate a plurality of measurement values of the plurality of power consumption levels. For example, to address the problem of asynchrony between multiple power consumption level measurement devices in the prior art, the time-division multiplexing calculator 120 of the present disclosure can set the plurality of power consumption levels at the common time reference, such that the plurality of power consumption levels synchronize to each other.

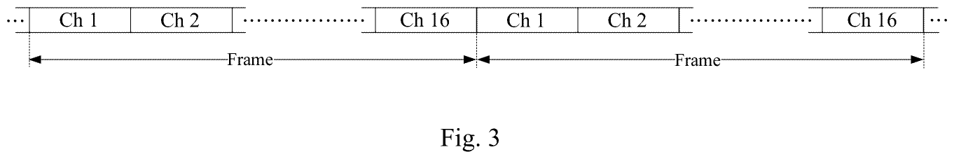

FIG. 3 shows an embodiment of power consumption levels and time frames of the present disclosure. As shown in the figure, the time-division multiplexing calculator 120 can set the plurality of power consumption levels in the same time frame. For example, the time-division multiplexing calculator 120 can set the plurality of power consumption levels obtained by the plurality of channels Ch1˜Ch16 of the time-division multiplexing meter 110 in the same time frame so as to calculate the plurality of measurement values of the plurality of power consumption levels.

In some embodiments, the time-division multiplexing calculator 120 can be a System on a Chip (SoC). However, the above-mentioned embodiment is merely utilized to describe one of the implementations, and the present disclosure is not limited thereto. In another embodiment, the time-division multiplexing calculator 120 can be implemented by other electronic device/element based on actual requirements.

In some embodiments, the time-division multiplexing meter 110 of the present disclosure can be an audio time-division multiplexing analog-to-digital converter (ADC). The audio time-division multiplexing analog-to-digital converter 110 can apply the concept of multi-channel audio input into measure situations of multiple power rails for achieving multi-channel analog-to-digital conversion (ADC) functionality. It combines the analog-to-digital conversion (ADC) input data from different channels in the same time frame, thereby achieving synchronization. In some embodiments, the audio sampling rate of the audio time-division multiplexing analog-to-digital converter 110 is 48 kHz, which is sufficient for measuring the power consumption level of the power rail.

It is noted that the present disclosure is not limited to the embodiments as shown in FIG. 1 to FIG. 3, it is merely an example for illustrating one of the implements of the present disclosure, and the scope of the present disclosure shall be defined on the bases of the claims as shown below. In view of the foregoing, it is intended that the present disclosure covers modifications and variations to the embodiments of the present disclosure, and modifications and variations to the embodiments of the present disclosure also fall within the scope of the following claims and their equivalents.

As described above, technical features of some embodiments of the present disclosure make an improvement to the prior art. The power consumption level measurement device and the power consumption level measurement method of the present disclosure can synchronously measure the power consumption levels of the plurality of devices under test to address the problem of asynchrony between the power consumption level measurement devices. Besides, the present disclosure only needs to use a single power consumption level measurement device for executing the power consumption level measurement, thereby saving costs, and reducing measurement complexity.

It is noted that people having ordinary skill in the art can selectively use some or all of the features of any embodiment in this specification or selectively use some or all of the features of multiple embodiments in this specification to implement the present invention as long as such implementation is practicable; in other words, the way to implement the present invention can be flexible based on the present disclosure.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A power consumption level measurement device, comprising:
a time-division multiplexing meter, comprising:
a plurality of measurement terminals, configured to respectively measure a plurality of power consumption levels of a plurality of devices under test; and
a time-division multiplexing calculator, configured to set the plurality of power consumption levels to a common time reference, and calculate a plurality of measurement values of the plurality of power consumption levels.

2. The power consumption level measurement device of claim 1, wherein the time-division multiplexing calculator is configured to set the plurality of power consumption levels to the common time reference, such that the plurality of power consumption levels synchronize to each other.

3. The power consumption level measurement device of claim 1, wherein the time-division multiplexing calculator sets the plurality of power consumption levels in a same time frame so as to calculate the plurality of measurement values of the plurality of power consumption levels.

4. The power consumption level measurement device of claim 1, wherein the time-division multiplexing calculator comprise a system on a chip.

5. The power consumption level measurement device of claim 1, wherein the time-division multiplexing meter comprise a time-division multiplexing analog-to-digital converter.

6. The power consumption level measurement device of claim 1, wherein a number of the plurality of measurement terminals comprises at least five.

7. The power consumption level measurement device of claim 1, wherein the plurality of measurement terminals comprise a plurality of channels.

8. A power consumption level measure method, comprising:
respectively measuring a plurality of power consumption levels of a plurality of devices under test by a plurality of measurement terminals of a time-division multiplexing meter; and
setting the plurality of power consumption levels to a common time reference and calculating a plurality of measurement values of the plurality of power consumption levels by a time-division multiplexing calculator.

9. The power consumption level measurement method of claim 8, wherein setting the plurality of power consumption levels to the common time reference and calculating the plurality of measurement values of the plurality of power consumption levels by the time-division multiplexing calculator comprises:
setting the plurality of power consumption levels to the common time reference by the time-division multiplexing calculator, such that the plurality of power consumption levels synchronize to each other.

10. The power consumption level measurement method of claim 8, wherein setting the plurality of power consumption levels to the common time reference and calculating the plurality of measurement values of the plurality of power consumption levels by the time-division multiplexing calculator comprises:
setting the plurality of power consumption levels in a same time frame so as to calculate the plurality of measurement values of the plurality of power consumption levels by the time-division multiplexing calculator.
